(19) United States
(12) Patent Application Publication
(10) Pub. No.: US 2024/0232461 A1
(43) Pub. Date: Jul. 11, 2024

(54) SIGNAL VIRTUALIZATION USING AN ENSEMBLE OF WEAK IMPUTATIONS

(71) Applicant: Dell Products L.P., Round Rock, TX (US)

(72) Inventors: Herberth Birck Fröhlich, Florianópolis (BR); Ítalo Gomes Santana, Rio de Janeiro (BR); Yanexis Pupo Toledo, Niterói (BR); Werner Spolidoro Freund, Rio de Janeiro (BR)

(21) Appl. No.: 18/153,092

(22) Filed: Jan. 11, 2023

(51) Int. Cl. G06F 30/20

(52) U.S. Cl. CPC G06F 30/20

(57) ABSTRACT

Signal virtualization using an ensemble of imputation operations is disclosed. In a digital twin, observations or data points are imputed using a combination of imputation operations. The imputed observations are generated between checkpoint operations, which correspond to observations from a data source. The number of imputed observations can be determined in advance.

### FIELD OF THE INVENTION

Embodiments of the present invention generally relate to digital twins. More particularly, at least some embodiments of the invention relate to systems, hardware, software, computer-readable media, and methods for estimating signal sources and output in applications including digital twin applications.

### BACKGROUND

Generally, a digital twin is a digital version of a real-world physical system. A digital twin, in other words, may digitally represent a real system. While digital twin can be viewed as models of a physical system, digital twins also have additional benefits and capabilities. A digital twin can receive data from data sources in the physical system, for example. This allows the digital twin to, in effect, operate in parallel with the physical system. Using real data from the physical system allows the digital twin to perform simulations using real data to determine how, for example, a product or process will perform. In addition to modeling a physical system, the digital twin can also simulate proposed products or processes prior to implementation.

In the context of data services, digital twins may have various capabilities including data acquisition/ingestion and data streaming. The efficiency of these capabilities is often related to the volume of data ingested into the digital twin. In fact, the amount of data ingested into a digital twin may become too large. This may occur when data comes from multiple data sources or multiple databases. The volume of data may increase to prohibitive levels as data may come from multiple sources and/or databases. Failing to observe the limitations (e.g., data ingestion volumes, data transfer rates) of a digital twin may adversely impact the operation of the digital twin and can hinder the use of related services where storage and bandwidth are limiting factors.

### BRIEF DESCRIPTION OF THE DRAWINGS

In order to describe the manner in which at least some of the advantages and features of the invention may be obtained, a more particular description of embodiments of the invention will be rendered by reference to specific embodiments thereof which are illustrated in the appended drawings. Understanding that these drawings depict only typical embodiments of the invention and are not therefore to be considered to be limiting of its scope, embodiments of the invention will be described and explained with additional specificity and detail through the use of the accompanying drawings, in which:

FIG. 1 discloses aspects of a digital twin framework or system;

FIG. 2 discloses aspects of generating imputed observations;

FIG. 3 discloses aspects of training a forecasting model using a sliding window, data points, and a context of a physical entity;

FIG. 4 discloses aspects of generating imputed observations in a digital twin; and

FIG. 5 discloses aspects of a computing device, system, or entity.

### DETAILED DESCRIPTION OF SOME EXAMPLE EMBODIMENTS

Embodiments of the present invention generally relate to digital twins and digital twin operations. More particularly, at least some embodiments of the invention relate to systems, hardware, software, computer-readable media, and methods for imputation operations to impute data in digital twin systems and frameworks.

A digital twin is typically a digital version of a physical system. When used in a data services context, the capabilities of a digital twin may relate to data acquisition/ingestion and data streaming. In many situations, the data being ingested may include or relate to well behaved signals. For example, data from a sensor may be substantially reliable over time. As a result, anomalies can be neglected.

One concern is that the amount of data acquired or ingested may be large and impact the requirements and/or the performance of the digital twin. Embodiments of the invention relate to reducing the volume of data streamed to a digital twin and reducing storage requirements of the digital twin. This may be achieved by estimating data points or data values using imputation methods. These imputation methods may be used on demand. Imputing data points or values is an example of signal virtualization.

More specifically, the digital twin operations or imputation operations are performed to estimate or generate imputed data points or values rather than ingest actual data points or values. This reduces data streaming and storage requirements for the real or physical data points or values. Embodiments of the invention may also collect actual or physical data points or values periodically or occasionally as checkpoint data or values.

Embodiments of the invention include ensemble-based imputation methods to generate data points between checkpoints. The checkpoints may include real or physical data generated or received from data sources in an environment and the imputed data is generated between the checkpoints. In one example, a predetermined number of data points or values are not collected. The predetermined number of imputed data points or values are generated. Imputing data points or values can reduce communication volume between a physical entity and the storage of a digital twin. The imputation operations may also be performed as-a-service.

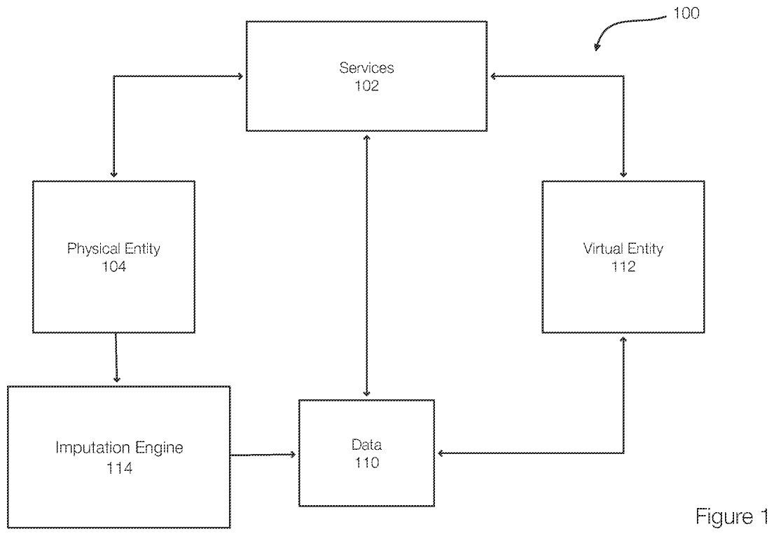

FIG. 1 discloses aspects of a digital twin framework or system. By way of example, a digital twin framework or system may include five dimensions: physical entity, virtual entity, services, connection, and digital data. The digital twin system 100 include a physical entity 104. The physical entity 104 may include or represent various systems, subsystems and sensory devices, such as, but not limited to, a dynamic system, a control system, a hydraulic system, sensors, design, manufacturing, or the like. The virtual entity 112 (the digital twin) is a mirror of the physical entity 104 and may include geometry models, physics models, behavior models, rule models, or the like or combination thereof.

The services 102 are configured to ensure that the physical entity 104 operates as expected and sustains high-fidelity of the virtual entity 112 through model parameters calibration. For the physical entity 104, the services 102 may include monitoring, state prediction, optimization, or the like. For the virtual entity 112, the services may include construction services, calibration services, test service models, and the like. The connections represent possible connections, which may be bidirectional, between the services 102, the physical entity 104, the virtual entity 112, and data 110. The data 110 may be a database that stores data from the physical entity 104, the virtual entity 112, from services 102, and fusions or combinations thereof. The data 110 is representative of storage devices and/or the data stored thereon.

The virtual entity 112, or digital twin, may be associated with or include an imputation engine 114. The imputation engine 114 may be configured to impute data. By imputing data, which includes generating or estimating data points or values between checkpoints, the bandwidth consumed between the physical entity 104 and the data 110 can be substantially reduced. For example, if a sensor is configured to sense wind speed, a first checkpoint may include data (e.g., an observation) generated by the sensor at time t₀. At a time t₁₀, another checkpoint or observation may be obtained from the sensor. For times between t₀ and t₁₀ (t₁₋₉) data values or observations are imputed by the imputation engine 114. Thus, the need to transmit/collect these values or observations is avoided and bandwidth is not consumed. Storage requirements may also be reduced at least because imputed observations may not need to be stored. The savings can be significant when considering multiple data sources that may be generating data at relatively high rates.

In one example, the observations (data points, data values, etc.) collected or received from various types of data sources are interrupted or disrupted with a given pattern. The disrupted intervals are filled with plausible or imputed observations at some frequency.

More specifically, embodiments of the invention relate to digital twins with data service capabilities. A data service may be responsible for intermittently collecting data from a physical entity. The data service may include an imputation engine that allows imputed data to be stored in the database or storage of the digital twin. The imputed data can be used and deleted if necessary. Within the data service, data streaming is considered as a service category. In this service category, continuous packets of information that are changing at high speed may be acquired to obtain real-time insights.

The disruption pattern implemented by the imputation engine may sample or obtain one checkpoint observation per a predefined set of observations. The choice of sensor that has its signal volume reduced and the number of imputed or observations between checkpoints (NBC) can be determined by a user or set by default. The NBC value represents the number of data points or observations that will be imputed by the imputation engine.

Embodiments of the invention may rely on forecasting models to generate the imputed observations while, at the same time, reduce data flow and data volume. Data volume and/or flow reductions can benefit cloud and edge-based digital twins and low storage requirements can benefit edge devices with embedded digital twins.

In one example, observations are imputed using, by way of example only, multiple imputation methods such as i) Last Observation is Carried Forwards (LOCF), ii) Next Observation is Carried Backward (NOCB), iii) Rolling Moving Average (RMA), and iv) a forecasting model (FM) that predicts two data points or observations ahead.

In LOCF, the current observation is carried forward. As a result, the observation at time t is the same as the observation at time t+1. RMA aids in avoiding fluctuations by incorporating a trend from a previous interval. In one example, the average of NBC+1 previous points or observations is replicated to the imputed observation for observation t+1.

A forecasting model may include a trained multioutput regressor model that predicts two points ahead of the current observation. Thus, the output H₁ is output for observation t+1 and the output H₂ is output for observation t+2. In NOCB, the second forecasted point H₂ is brought backwards.

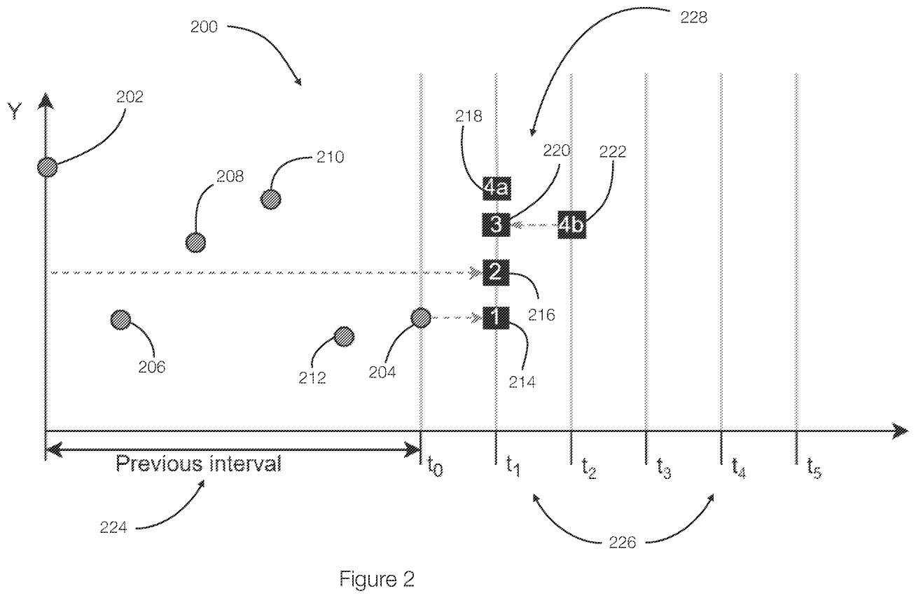

FIG. 2 illustrates an example of imputing observations. More specifically, FIG. 2 discloses aspects of imputing observations or data points from a data source in or for consumption by a data twin. FIG. 2 illustrates a timeline 200 that includes observations at different points in time. FIG. 2 illustrates two intervals 224, and 226. Each of the intervals is bounded by checkpoint observations. The interval 224 is a previous interval and the interval 226 is a current interval. The current interval includes points or observations corresponding to times t₀, t₁, t₂, t₃, t₄, and t₅. The previous interval includes the same number of points that may be labeled similarly.

Thus, the observation 202 is a checkpoint observation and corresponds to a real sample or observation from a physical system at a time labeled t₀. The observation 204 is also a checkpoint observation that corresponds to a real sample or observation from the physical system at the next time t₀. In this example, NBC=4. Thus, the imputed observations include the observations 206, 208, 210, and 212.

After acquiring or ingesting the checkpoint observation 204, the next imputed observation 228 is generated. The imputed observation 228 is determined from outputs of, in this example, four imputation methods. The imputed value 1 that contributes to the observation 228 is generated using LOCF. Thus, the observation 204 is carried forward and becomes the imputed observation 214. The imputed value 2 that contributes to the observation 228 is generated using RMA. Thus, the value 2 for the observation 228 is generated as an average of the previous NBC+1 observations. More specifically, the observations 204, 212, 210, 208, and 206 are averaged to determine a value or other representation of the imputed observation 216.

Next, the value 4a is generated using the forecasting model. As previously stated, the forecasting model generates two values: H₁ (4a) and H₂ (4b). The value of the imputed observation 218 that contributes to the imputed observation 228 is the value 4a or the first output H₁ of the forecasting model.

The value 3 that contributes to the observation 228 is generated using NOCB. In this example, the second value or output of the forecasting model (4b) is brought back as the value 3 and becomes the imputed observation 220.

Each of these four methods generates corresponding imputed observation 214, 216, 220, and 218. The imputed observation 228 that is associated with time t₁ may be generated by averaging the imputed observations 214, 216, 218, and 220.

Thus, the imputed observation 228 may be determined as follows:

$${Value}_{t + 1} = \frac{( {Value}_{L O C F} + {Value}_{NOCB} + {Value}_{R M A} + {Value}_{forecasting}}{4} .$$

In some examples, the imputed observations 214, 216, 218, and 220 may be weighted. For the next imputed observation corresponding to t₂, the recently imputed observations and/or checkpoint observations are used as previously described.

Using an ensemble of imputation operations to determine a particular imputed observation, in contrast to a single imputation operation such as forecasting, may trade lower statistical variance for increased bias. This is advantageous where fluctuations are due to noise. In addition, embodiments of the invention also adapt to changes smoothly.

Embodiments of the invention may be achieved in stages including an offline stage and an online stage. In the offline stage, data and domain context points or observations may be obtained and the forecasting model may be trained. In addition to historical observations, which include data points or values of data from the data sources, different contexts can improve the generalization of the forecasting models as the contexts may provide information to reduce spurious variational factors.

Context points such as rotations per minute (RPMs) and power may come from the physical entity. If this context changes, the signal coming from the sensors will likely change as well. This is one reason why context is added to the training dataset. These points (data and/or context) should be available within the digital twin framework and may come from the virtual entity.

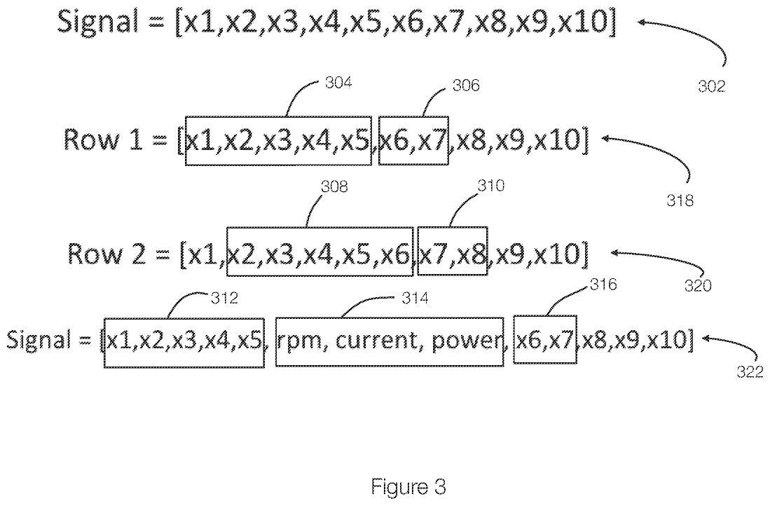

FIG. 3 discloses aspects of an offline stage for training a forecasting model. The example of FIG. 3 assumes that NBC=4. Thus, there are 4 imputed values or observations between checkpoint values or observations. In this example, the signal 302 is obtained, for example from historical observations. The signal 302 may be one of many historical signals used during training. The signal 302 includes 10 observations. When training, the observations are real observations in one example. Because NBC=4, 5 observations (4+1) are used for training. Thus, the first row input to the training operation includes the observations 304 in the row 318. The observations 306 correspond to the H₁ and H₂ values or to the values that the model is learning to predict.

In the context of training, the observations 304 are the features and the observations 306 are the targets for training purposes.

For the row 320 or the next input, the window used to select observations is moved to the next sequence of observations in a sliding-window manner. Thus, the observations 308 are the features and the observations 310 are the targets (the H₁ and H₂ values).

As previously stated, however, context may change. The signal 322 thus represents a full observation. The signal 322 includes observations 312, device information 314 (an example of context) and target observations 316.

The forecasting model may be a multioutput regressor that can be trained using this type of data and a sliding window approach to the signal or training data. In one example, a regressor is trained for each of the targets (e.g., one regressor for H₁ and one regressor for H₂).

Once the forecasting model is trained, the online stage may be performed. In the online stage, imputation operations are performed to generate imputed observations between checkpoint observations.

The NBC number, in addition to representing the number of imputed observations between checkpoint observations, may also represent time between checkpoint observations. While larger NBC or time values may correspond to fewer data from the physical entity, inaccuracy in the imputed observations may also increase. Error tends to increase with larger NBC values due, in part, to less frequent checkpoint observations.

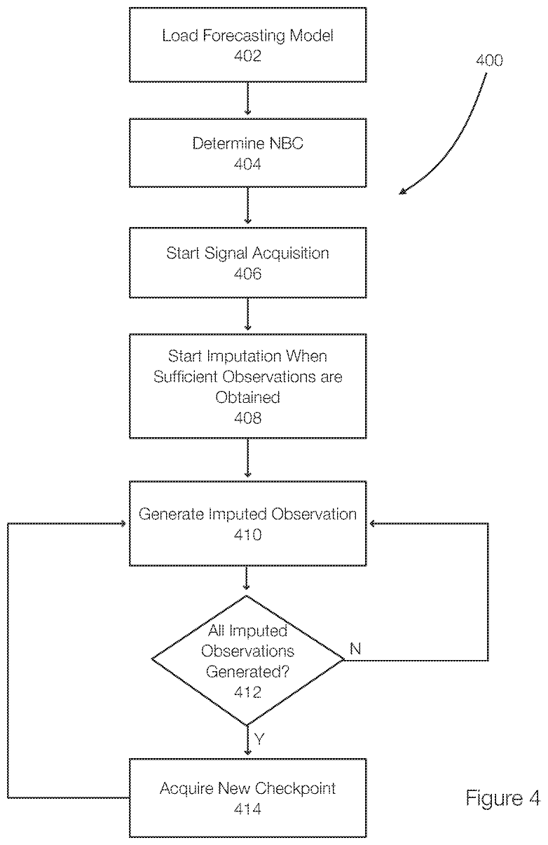

FIG. 4 discloses aspects of an online stage for generating imputed observations. The method 400 includes loading 402 a forecasting model. The forecasting model was trained, by way of example, during the offline stage using historical values, which may include observations and/or context.

Next, the number of points (observations) or NBC between checkpoints is determined 404. The NBC may be set by a user, determined by default, or determined in another manner. Next, signal acquisition is started 406. Stated differently, observations are collected or retrieved from a data source. In one example, a sufficient number of real observations are collected because the imputation methods, including RMA, relies on a certain number of previous observations. Thus, at the beginning, a number of real observations may be collected without disruption. This allows the imputation operation to proceed with sufficient data once the imputation operation begins. Once a sufficient number of observations has been collected, imputation is started 408. In one example, a sufficient number of observations required prior to starting the imputation operation is NBC+1. In this example, the last observation is a first checkpoint observation.

Next, an imputed observation is generated 410. If the number of imputed observations generated is sufficient are generated (Y at 412), a new checkpoint observation is acquired 414 and the process returns to generating imputed observations. If sufficient imputed observations have not been generated (N at 412), the next imputed observation is generated 410. A sufficient number of imputed observations have been generated when the number of imputed observations generated is NBC imputed observations.

When generating 410 imputed observations, a sliding window may be used as previously described on the observations being processed, which may include imputed observations. Stated differently, generating a value or data point for a current observation may rely on a number of previous observations, which may include checkpoint observations and/or imputed observations, and the forecasted observations.

When generating imputed observations 410, multiple imputation methods are applied to the various data points (previous imputed/checkpoint observations and/or forecasted observations). The results of the multiple imputation methods are combined (e.g., averaged, weighted average) to generate a final imputed observation that may be used by the digital twin.

For example, if the NBC value is 9, this indicates that checkpoint observations are being collected every 10 observations. This saves 90% of the bandwidth. Embodiments of the invention thus provide bandwidth reduction for various digital twin applications including edge and cloud-based digital twin applications. Embodiments of the invention may also reduce storage requirements for digital twin systems. This is advantageous for digital twin systems that have smaller storage capabilities.

The following is a discussion of aspects of example operating environments for various embodiments of the invention. This discussion is not intended to limit the scope of the invention, or the applicability of the embodiments, in any way.

In general, embodiments of the invention may be implemented in connection with systems, software, and components, that individually and/or collectively implement, and/or cause the implementation of, digital twin operations, imputation operations, imputed observation generation operations, or the like. More generally, the scope of the invention embraces any operating environment in which the disclosed concepts may be useful.

New and/or modified data collected and/or generated in connection with some embodiments, may be stored in a data storage environment that may take the form of a public or private cloud storage environment, an on-premises storage environment, and hybrid storage environments that include public and private elements. Any of these example storage environments, may be partly, or completely, virtualized.

Example cloud computing environments, which may or may not be public, include storage environments that may provide data protection functionality for one or more clients. Another example of a cloud computing environment is one in which processing, data protection, and other, services may be performed on behalf of one or more clients. Some example cloud computing environments in connection with which embodiments of the invention may be employed include, but are not limited to, Microsoft Azure, Amazon AWS, Dell EMC Cloud Storage Services, and Google Cloud. More generally however, the scope of the invention is not limited to employment of any particular type or implementation of cloud computing environment.

In addition to the cloud environment, the operating environment may also include one or more clients that are capable of collecting, modifying, and creating, data. As such, a particular client may employ, or otherwise be associated with, one or more instances of each of one or more applications that perform such operations with respect to data. Such clients may comprise physical machines, containers, or virtual machines (VMs).

Particularly, devices in the operating environment may take the form of software, physical machines, containers, or VMs, or any combination of these, though no particular device implementation or configuration is required for any embodiment. Similarly, data protection system components such as databases, storage servers, storage volumes (LUNs), storage disks, replication services, backup servers, restore servers, backup clients, and restore clients, for example, may likewise take the form of software, physical machines or virtual machines (VM), though no particular component implementation is required for any embodiment.

As used herein, the term ‘data’ is intended to be broad in scope. Thus, that term embraces, by way of example and not limitation, data segments such as may be produced by data stream segmentation processes, data chunks, data blocks, atomic data, emails, objects of any type, files of any type including media files, word processing files, spreadsheet files, and database files, as well as contacts, directories, sub-directories, volumes, and any group of one or more of the foregoing. Data may also include sensor data or other data generated in a computing system, a physical system, a digital twin system, or the like and/or data received from data sources in an environment.

It is noted that any operation(s) of any of these methods disclosed herein, may be performed in response to, as a result of, and/or, based upon, the performance of any preceding operation(s). Correspondingly, performance of one or more operations, for example, may be a predicate or trigger to subsequent performance of one or more additional operations. Thus, for example, the various operations that may make up a method may be linked together or otherwise associated with each other by way of relations such as the examples just noted. Finally, and while it is not required, the individual operations that make up the various example methods disclosed herein are, in some embodiments, performed in the specific sequence recited in those examples. In other embodiments, the individual operations that make up a disclosed method may be performed in a sequence other than the specific sequence recited.

Following are some further example embodiments of the invention. These are presented only by way of example and are not intended to limit the scope of the invention in any way.

Embodiment 1. A method comprising: collecting a set of initial observations from a data source associated with a system, wherein the set of initial observations includes a predetermined number of observations from the data source and a first checkpoint observation, after collecting the first checkpoint observation, generating the predetermined number of imputed observations, after generating the predetermined number of the imputed observations, collecting a next checkpoint observation from the data source, and operating a digital twin using the imputed observations.

Embodiment 2. The method of embodiment 1, wherein each of the imputed observations is generated using multiple imputation operations.

Embodiment 3. The method of embodiment 1 and/or 2, wherein the imputed operations include two or more of a last observation is carried forwards operation, a next observation is carried backward operation dependent on the forecasting model, a rolling moving average operation, and a forecasting model.

Embodiment 4. The method of embodiment 1, 2, and/or 3, wherein each of the imputed observations is a combination of outputs of the multiple imputation operations.

Embodiment 5. The method of embodiment 1, 2, 3, and/or 4, wherein the combination is an average or a weighted average of the outputs.

Embodiment 6. The method of embodiment 1, 2, 3, 4, and/or 5, further comprising determining the predetermined number of observations, wherein the predetermined number of observations equal a number of imputed observations between sequential checkpoint operations.

Embodiment 7. The method of embodiment 1, 2, 3, 4, 5, and/or 6, further comprising determining the predetermined number of observations to balance bandwidth conservation and accuracy.

Embodiment 8. The method of embodiment 1, 2, 3, 4, 5, 6, and/or 7, further comprising training a forecasting model using historical observations, wherein the historical observations include input data observations, a context and target data observations.

Embodiment 9. The method of embodiment 1, 2, 3, 4, 5, 6, 7, and/or 8, wherein the context is acquired from the digital twin or a physical entity modeled by the digital twin.

Embodiment 10. The method of embodiment 1, 2, 3, 4, 5, 6, 7, 8, and/or 9, wherein the digital twin is configured to stream data or to receive streamed data from the data source and is associated with a physical entity.

Embodiment 11 A system, comprising hardware and/or software, operable to perform any of the operations, methods, or processes, or any portion of any of these, or any combination thereof disclosed herein.

Embodiment 12. A non-transitory storage medium having stored therein instructions that are executable by one or more hardware processors to perform operations comprising the operations of any one or more of embodiments 1-11.

The embodiments disclosed herein may include the use of a special purpose or general-purpose computer including various computer hardware or software modules, as discussed in greater detail below. A computer may include a processor and computer storage media carrying instructions that, when executed by the processor and/or caused to be executed by the processor, perform any one or more of the methods disclosed herein, or any part(s) of any method disclosed.

As indicated above, embodiments within the scope of the present invention also include computer storage media, which are physical media for carrying or having computer-executable instructions or data structures stored thereon. Such computer storage media may be any available physical media that may be accessed by a general purpose or special purpose computer.

By way of example, and not limitation, such computer storage media may comprise hardware storage such as solid state disk/device (SSD), RAM, ROM, EEPROM, CD-ROM, flash memory, phase-change memory (“PCM”), or other optical disk storage, magnetic disk storage or other magnetic storage devices, or any other hardware storage devices which may be used to store program code in the form of computer-executable instructions or data structures, which may be accessed and executed by a general-purpose or special-purpose computer system to implement the disclosed functionality of the invention. Combinations of the above should also be included within the scope of computer storage media. Such media are also examples of non-transitory storage media, and non-transitory storage media also embraces cloud-based storage systems and structures, although the scope of the invention is not limited to these examples of non-transitory storage media.

Computer-executable instructions comprise, for example, instructions and data which, when executed, cause a general-purpose computer, special purpose computer, or special purpose processing device to perform a certain function or group of functions. As such, some embodiments of the invention may be downloadable to one or more systems or devices, for example, from a website, mesh topology, or other source. As well, the scope of the invention embraces any hardware system or device that comprises an instance of an application that comprises the disclosed executable instructions.

Although the subject matter has been described in language specific to structural features and/or methodological acts, it is to be understood that the subject matter defined in the appended claims is not necessarily limited to the specific features or acts described above. Rather, the specific features and acts disclosed herein are disclosed as example forms of implementing the claims.

As used herein, the term ‘module’ or ‘component’ may refer to software objects or routines that execute on the computing system. The different components, modules, engines, and services described herein may be implemented as objects or processes that execute on the computing system, for example, as separate threads. While the system and methods described herein may be implemented in software, implementations in hardware or a combination of software and hardware are also possible and contemplated. In the present disclosure, a ‘computing entity’ may be any computing system as previously defined herein, or any module or combination of modules running on a computing system.

In at least some instances, a hardware processor is provided that is operable to carry out executable instructions for performing a method or process, such as the methods and processes disclosed herein. The hardware processor may or may not comprise an element of other hardware, such as the computing devices and systems disclosed herein.

In terms of computing environments, embodiments of the invention may be performed in client-server environments, whether network or local environments, or in any other suitable environment. Suitable operating environments for at least some embodiments of the invention include cloud computing environments where one or more of a client, server, or other machine may reside and operate in a cloud environment.

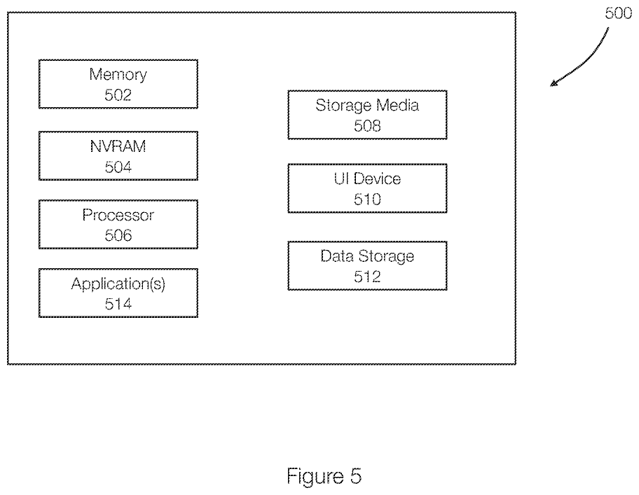

With reference briefly now to FIG. 5, any one or more of the entities disclosed, or implied, by the Figures and/or elsewhere herein, may take the form of, or include, or be implemented on, or hosted by, a physical computing device, one example of which is denoted at 500. As well, where any of the aforementioned elements comprise or consist of a virtual machine (VM) (or container), that VM may constitute a virtualization of any combination of the physical components disclosed in FIG. 5.

In the example of FIG. 5, the physical computing device 500 includes a memory 502 which may include one, some, or all, of random-access memory (RAM), non-volatile memory (NVM) 504 such as NVRAM for example, read-only memory (ROM), and persistent memory, one or more hardware processors 506, non-transitory storage media 508, UI device 510, and data storage 512. One or more of the memory components 502 of the physical computing device 500 may take the form of solid-state device (SSD) storage. As well, one or more applications 514 may be provided that comprise instructions executable by one or more hardware processors 506 to perform any of the operations, or portions thereof, disclosed herein.

Such executable instructions may take various forms including, for example, instructions executable to perform any method or portion thereof disclosed herein, and/or executable by/at any of a storage site, whether on-premises at an enterprise, or a cloud computing site, client, datacenter, data protection site including a cloud storage site, or backup server, to perform any of the functions disclosed herein. As well, such instructions may be executable to perform any of the other operations and methods, and any portions thereof, disclosed herein.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method comprising:
collecting a set of initial observations from a data source associated with a system, wherein the set of initial observations includes a predetermined number of observations from the data source and a first checkpoint observation;
after collecting the first checkpoint observation, generating the predetermined number of imputed observations;
after generating the predetermined number of the imputed observations, collecting a next checkpoint observation from the data source; and
operating a digital twin using the imputed observations.

2. The method of claim 1, wherein each of the imputed observations is generated using multiple imputation operations.

3. The method of claim 2, wherein the imputed operations include two or more of a last observation is carried forwards operation, a next observation is carried backward operation dependent on the forecasting model, a rolling moving average operation, and a forecasting model.

4. The method of claim 3, wherein each of the imputed observations is a combination of outputs of the multiple imputation operations.

5. The method of claim 4, wherein the combination is an average or a weighted average of the outputs.

6. The method of claim 1, further comprising determining the predetermined number of observations, wherein the predetermined number of observations equal a number of imputed observations between sequential checkpoint operations.

7. The method of claim 1, further comprising determining the predetermined number of observations to balance bandwidth conservation and accuracy.

8. The method of claim 1, further comprising training a forecasting model using historical observations, wherein the historical observations include input data observations, a context and target data observations.

9. The method of claim 1, wherein the context is acquired from the digital twin or a physical entity modeled by the digital twin.

10. The method of claim 1, wherein the digital twin is configured to stream data or to receive streamed data from the data source and is associated with a physical entity.

11. A non-transitory storage medium having stored therein instructions that are executable by one or more hardware processors to perform operations comprising:
collecting a set of initial observations from a data source associated with a system, wherein the set of initial observations includes a predetermined number of observations from the data source and a first checkpoint observation;
after collecting the first checkpoint observation, generating the predetermined number of imputed observations;
after generating the predetermined number of the imputed observations, collecting a next checkpoint observation from the data source; and
operating a digital twin using the imputed observations.

12. The non-transitory storage medium of claim 11, wherein each of the imputed observations is generated using multiple imputation operations.

13. The non-transitory storage medium of claim 12, wherein the imputed operations include two or more of a last observation is carried forwards operation, a next observation is carried backward operation dependent on the forecasting model, a rolling moving average operation, and a forecasting model.

14. The non-transitory storage medium of claim 13, wherein each of the imputed observations is a combination of outputs of the multiple imputation operations.

15. The non-transitory storage medium of claim 14, wherein the combination is an average or a weighted average of the outputs.

16. The non-transitory storage medium of claim 11, further comprising determining the predetermined number of observations, wherein the predetermined number of observations equal a number of imputed observations between sequential checkpoint operations.

17. The non-transitory storage medium of claim 11, further comprising determining the predetermined number of observations to balance bandwidth conservation and accuracy.

18. The non-transitory storage medium of claim 11, further comprising training a forecasting model using historical observations, wherein the historical observations include input data observations, a context and target data observations.

19. The non-transitory storage medium of claim 11, wherein the context is acquired from the digital twin or a physical entity modeled by the digital twin.

20. The non-transitory storage medium of claim 11, wherein the digital twin is configured to stream data or to receive streamed data from the data source and is associated with a physical entity.
